(19) United States
(12) Patent Application Publication
(10) Pub. No.: US 2001/0012659 A1
(43) Pub. Date: Aug. 9, 2001

(54) METHOD OF MANUFACTURING SEMICONDUCTOR DEVICE HAVING CAPACITOR

(75) Inventors: NAOYA SASHIDA, KANAGAWA (JP); KAZUAKI TAKAI, KANAGAWA (JP); MITSUHIRO NAKAMURA, KANAGAWA (JP); TATSUYA YAMAZAKI, KANAGAWA (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: FUJITSU LIMITED, KAWASAKI (JP)

(21) Appl. No.: 09/321,605

(22) Filed: May 28, 1999

(30) Foreign Application Priority Data
Dec. 10, 1998 (JP) 10-350892

(51) Int. Cl. H01L 21/8242; H01L 21/20

(52) U.S. Cl. 438/250; 438/253; 438/393

(57) ABSTRACT

The semiconductor device comprises an impurity diffusion layer formed on a semiconductor substrate, an insulating film for covering the impurity diffusion layer, a capacitor formed on the insulating film and consisting of a lower electrode, an oxide dielectric film, and an upper electrode, an interlayer insulating film for covering the capacitor, two opening portions formed in the interlayer insulating film to expose the impurity diffusion layer and the upper electrode, a local interconnection formed in two opening portions, and on the interlayer insulating film in a range containing at least a region where the upper electrode contacts the oxide dielectric film, and another interlayer insulating films for covering the local interconnection.

### BACKGROUND OF THE INVENTION

1. Field of the Invention

The present invention relates to a semiconductor device and a method of manufacturing the same and, more particularly, a semiconductor device having capacitors and a method of manufacturing the same.

2. Description of the Prior Art

A DRAM (Dynamic Random Access Memory) which is one of the semiconductor devices has memory cells in each of which a transistor is connected to a capacitor. Normally, a dielectric film of the capacitor is composed of silicon compound such as silicon dioxide, silicon nitride, etc. In contrast, there is an FeRAM (Ferroelectrics Random Access Memory) in which the dielectric film constituting the capacitor is composed of ferroelectric material. The FeRAM has such excellent features that it can achieve a reading rate and a writing rate which are equivalent to those of the DRAM and it has a nonvolatile property. For this reason, it can be anticipated that in the future the FeRAM will occupy the important position as the semiconductor memory device.

As such ferroelectric material, there are oxides such as Pb(Zr,Ti)O₃ which is called PZT, (Pb,La)(Zr,Ti)O₃ which is called PLZT, etc.

However, it has been known that, since the oxygen escapes from the ferroelectric film formed of the oxide when the ferroelectric film is exposed to the reduction atmosphere, film quality of the ferroelectric film is deteriorated and in turn electric characteristics of the capacitor is deteriorated, or the upper electrode formed on the ferroelectric film is ready to peel off the ferroelectric film formed of the oxide. Therefore, in the steps of manufacturing the semiconductor memory device, it is not preferable to employ silane (SiH₄) which has the reduction action as a reaction gas after the ferroelectric film has been formed. This is because reducing hydrogen is generated when the silane is decomposed.

Accordingly, when the capacitor including the ferroelectric film is covered with the interlayer insulating film, normally the film forming method which employs organic silicon compound material such as tetra ethoxy silane (TEOS), spin-on-glass (SOG), etc. in place of the silane is applied.

In this case, although an amount of the hydrogen is not so large as the silane, such organic silicon compound material also includes the hydrogen in itself. Therefore, the organic silicon compound material still causes the deterioration of characteristics of the capacitor which includes the ferroelectric film.

Therefore, it has been tried that, after the capacitor has been covered with the interlayer insulating film, film quality of the dielectric film of the capacitor is improved by providing openings to expose the upper electrode of the capacitor from the interlayer insulating film and then performing the oxygen-annealing the capacitor dielectric film via the openings. In this case, as material of the upper electrode, a metal such as platinum (Pt), iridium (Ir), ruthenium (Ru), or the like, which is hard to oxidize and whose conductivity is not lost even when oxidized, is employed.

Such oxygen-annealing is effective after the first interlayer insulating film has been formed on the capacitor. However, the oxygen-annealing cannot be applied after the second interlayer insulating film has been formed, for there is a possibility that, if the oxygen-annealing is carried out after the second interlayer insulating film has been formed, the wiring formed on the first interlayer insulating film is oxidized to thus increase its resistance.

In order to overcome this problem, as set forth in Patent Application Publication (KOKAI) Hei 7-235639, it is effective to form a wiring layer, which has a double-layered structure consisting of an aluminum film and a titanium-tungsten film, as the wiring formed on the first interlayer insulating film, in the range which covers the upper electrode of the capacitor. This is because diffusion of the hydrogen, which is generated in forming the second interlayer insulating film, into the capacitor can be blocked by the wiring layer and therefore the succeeding oxygen-annealing can be omitted.

However, the wiring layer consisting of the aluminum film and the titanium-tungsten film is unsuitable for fine patterning since it has the double-layered structure and thus is of large thickness. For this reason, if the ferroelectric capacitors which are formed in large numbers in the semiconductor memory device are incorporated with a high integration density, a distance between the capacitors becomes small below 1 μm, for example. As a result, the above structure that the capacitors are covered with the wiring layer which has a double layer structure cannot be implemented.

### SUMMARY OF THE INVENTION

It is an object of the present invention to provide a semiconductor device which can prevent oxidation of a wiring caused when the wiring connected to an upper electrode of a capacitor is covered with an insulating film, and prevent deterioration of an oxide dielectric film of the capacitor in forming the insulating film, and achieve higher integration of the capacitor, and a method of manufacturing the same.

The above problem can be overcome by providing a method of manufacturing a semiconductor device which comprises the steps of forming an impurity diffusion layer on a semiconductor substrate; forming a first insulating film covering the impurity diffusion layer; forming a lower electrode on the first insulating film; forming an oxide dielectric film on the lower electrode; forming an upper electrode for covering the oxide dielectric film; forming a capacitor by patterning the upper electrode, the oxide dielectric film, and the lower electrode; forming a second insulating film for covering the capacitor; forming a diffusion-layer opening portion which is connected electrically to the impurity diffusion layer and an upper-electrode opening portion which exposes the upper electrode, by patterning the second insulating film and the first insulating film; forming an oxidation-preventing metal film in the diffusion-layer opening portion and the upper-electrode opening portion and on the second insulating film; forming a local interconnection in a range which pass through the diffusion-layer opening portion and the upper-electrode opening portion and contains at least a region where the upper electrode contacts the oxide dielectric film, by patterning the metal film; and forming a third insulating film for covering the local interconnection.

The above problem can be overcome by providing a semiconductor device which comprises an impurity diffusion layer formed on a semiconductor substrate; a first insulating film for covering the impurity diffusion layer; a capacitor formed on the first insulating film and consisting of a lower electrode, an oxide dielectric film, and an upper electrode; a second insulating film for covering the capacitor; two opening portions formed in the second insulating film to expose the impurity diffusion layer and the upper electrode; a local interconnection formed in two opening portions and on the second insulating film in a range containing at least a region where the upper electrode contacts the oxide dielectric film; and a third insulating film for covering the local interconnection.

According to the present invention, the capacitor is covered with the local interconnection whose fine patterning can be achieved and the upper electrode of the capacitor and the impurity diffusion layer are connected by the local interconnection. Therefore, in the event that the capacitors employing the oxide dielectric film are fabricated with a high integration density, a plurality of capacitors can be covered individually with the local interconnections without fail respectively.

Accordingly, even when the hydrogen is generated in forming the insulating film on the local interconnections, hydrogen diffusion into the capacitors can be blocked by the local interconnections. Therefore, the oxygen-annealing to improve film quality of the oxide dielectric film after formation of the insulating film can be omitted. As a result, such a possibility can be eliminated that the local interconnections are oxidized, and also the highly integrated ferroelectric capacitors which have excellent characteristics can be implemented.

In addition, since an window is opened in the insulating film which is formed on the oxide dielectric film and then the oxide dielectric film and the upper electrode are formed via the window on the lower electrode, a size of the capacitor is restricted according to a size of the window formed in the insulating film. Since a patterning precision of the insulating film is higher than a patterning precision of the metal or conductive ceramic, such patterning precision of the insulating film can be adapted for the higher integration of the semiconductor memory device which employs the capacitor.

### BRIEF DESCRIPTION OF THE DRAWINGS

FIGS.1A to 1G are sectional views showing steps of manufacturing a semiconductor device according to a first embodiment of the present invention;

FIGS.2A and 2B are plan views showing a part of the steps of manufacturing the semiconductor device according to the first embodiment of the present invention;

FIG.3 is a characteristic view showing voltage polarization of a capacitor in the semiconductor device according to the first embodiment of the present invention;

FIG.4A is a plan view showing the capacitor formed for the sake of comparison;

FIG.4B is a characteristic view showing voltage polarization of the capacitor in FIG.4A;

FIGS.5A and 5D are sectional views showing steps of manufacturing a semiconductor device according to a second embodiment of the present invention; and

FIGS.6A to 6F are sectional views showing steps of manufacturing a semiconductor device according to a third embodiment of the present invention.

### DESCRIPTION OF THE PREFERRED EMBODIMENTS

Embodiments of the present invention will be explained in detail with reference to the accompanying drawings hereinafter.

First Embodiment

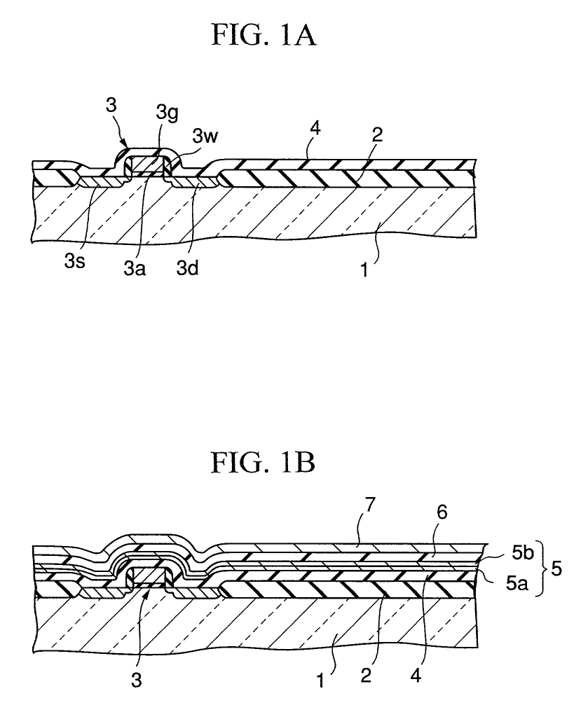

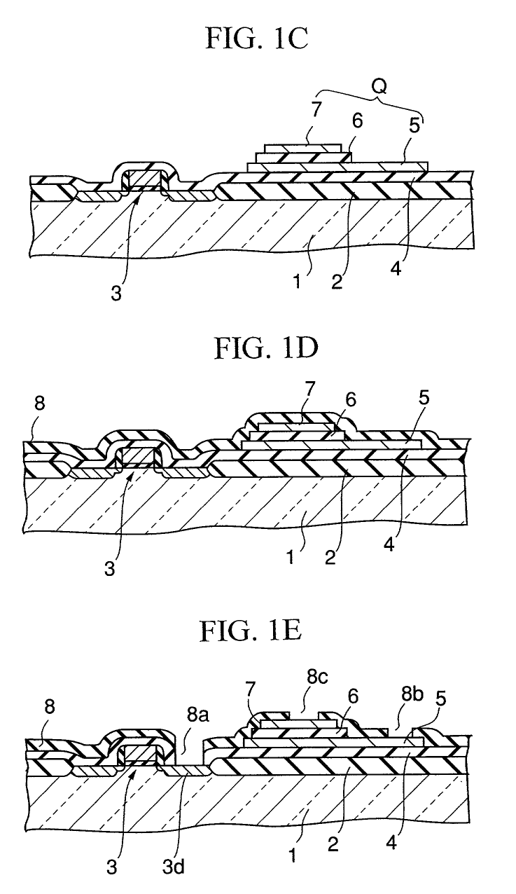

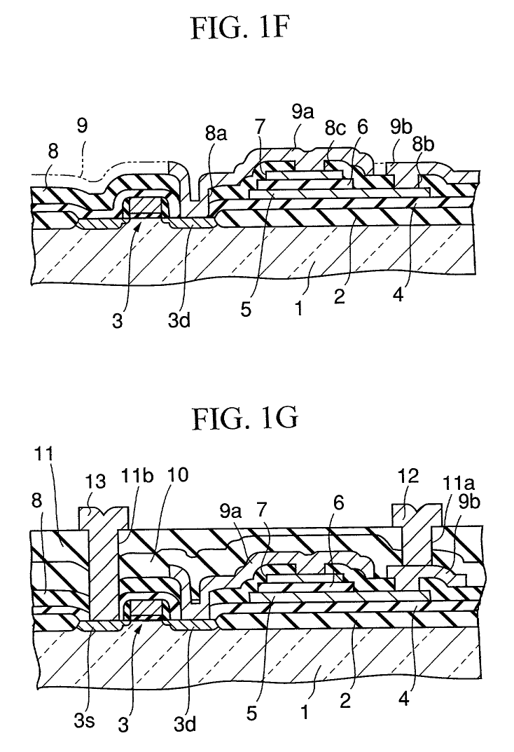

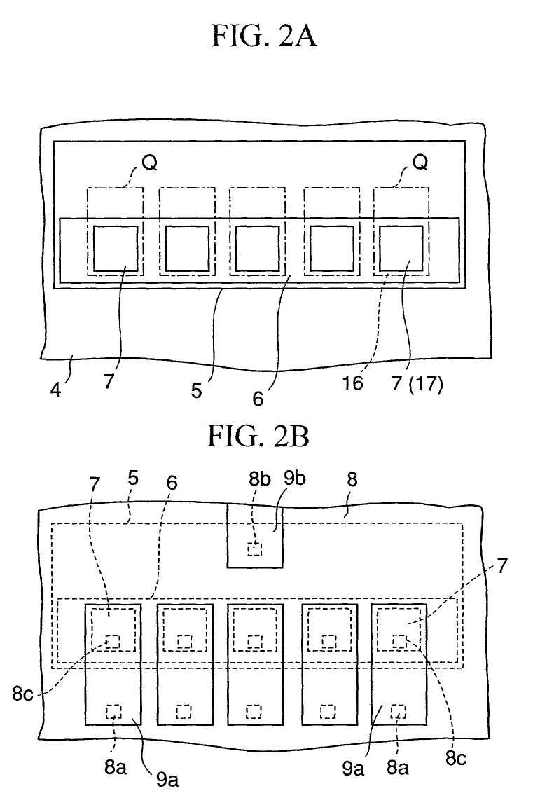

FIGS.1A to 1G are sectional views showing steps of manufacturing a semiconductor device according to a first embodiment of the present invention. FIG.2A is a plan view showing a configuration in FIG.1D, and FIG.2B is a plan view showing a configuration in FIG.1E.

To begin with, the steps needed to manufacture the configuration shown in FIG.1A will be explained hereunder.

In FIG.1A, a field oxide film 2 is formed around a transistor forming region on a surface of a p-type silicon substrate (semi-conductor substrate) 1. The field oxide film 2 is formed by the selective oxidation method which employs a pattern formed of silicon nitride, for example, as an oxidation preventing mask.

A MOS transistor 3 is then formed in the transistor forming region on the silicon substrate 1. The MOS transistor 3 is formed along following steps.

A silicon dioxide (SiO₂) film serving as a gate insulating film 3a is then formed on the surface of the silicon substrate 1 by the thermal oxidation method. A gate electrode 3g is then formed on the gate insulating film 3a. While using the gate electrode 3g as a mask, an n-type impurity such as phosphorus, arsenic, etc. is then ion-implanted into the silicon substrate 1 on both sides of the gate electrode 3g. In turn, insulative sidewalls 3w are formed on both side surfaces of the gate electrode 3g. While using the sidewalls 3w and the gate electrode 3g as a mask, the n-type impurity is then ion-implanted into the silicon substrate 1. According to such twice impurity ion implantation, first and second impurity diffusion layers 3d, 3s having an LDD configuration respectively are formed in the silicon substrate 1 on both side of the gate electrode 3g.

With the above, the steps of forming the MOS transistor 3 are completed.

Subsequently, a first interlayer insulating film 4 formed of silicon dioxide is formed on the field oxide film 2 and the MOS transistor 3 to have a thickness of 500 nm. The first interlayer insulating film 4 can be formed by the chemical vapor deposition method using silane (SiH₄) as the reaction gas.

A plurality of films of a capacitor are formed on the first interlayer insulating film 4 in the region where the field oxide film 2 is formed.

First, as shown in FIG.1B, a 20 nm thick titanium (Ti) film 5a and a 175 nm thick platinum (Pt) film 5b are formed in sequence on the first interlayer insulating film 4 by the sputter method. The Ti film 5a and the Pt film 5b are employed as a lower electrode 5 of the capacitor Q.

An oxide dielectric film 6 of the capacitor Q is then formed on the lower electrode 5. As the oxide dielectric film 6, for example, a PLZT film or a PZT film which is formed by the sputter method to have a thickness of 300 nm is available. The PLZT is obtained by adding lanthanum (La) into the PZT. This lanthanum is doped to improve capacitor characteristics. A composition ratio of constituent elements of the PLZT film, for example, lead (Pb), lanthanum (La), zirconium (Zr), and titanium (Ti) are set to 1.07, 0.03, 0.30, and 0.70 respectively.

After such oxide dielectric film 6 has been formed, RTA (Rapid Thermal Annealing) is then carried out in the oxygen-containing atmosphere at 850° C. for about 10 second to improve crystal property of the oxide dielectric film 6.

A platinum film is then formed on the oxide dielectric film 6 to have a thickness of 175 nm. This platinum film is employed as upper electrodes 7 of the capacitor Q.

The platinum film is then patterned into rectangular patterns of 2×2 μm², for example, by the plasma etching and the photolithography using resist, as shown in a plan view of FIG.2A. Thus, a plurality of upper electrodes 7 are formed separately at a distance of 1 μm. Positions of a plurality of capacitors Q can be defined by these rectangular upper electrodes 7. In this case, a gas containing chlorine (C1) is employed as an etchant of the Pt film.

Since damage is caused on the boundary between the upper electrodes 7 and the oxide dielectric film 6 in this etching, such damage is then removed by oxygen-annealing. This oxygen-annealing is effected by exposing the upper electrodes 7 and the oxide dielectric film 6 to the oxygen atmosphere at the substrate temperature of 650° C. for 60 minute. Oxygen is supplied to the oxide dielectric film 6 via the upper electrodes 7.

The oxide dielectric film 6 is then patterned by the photolithography method, as shown in FIG.2A, to be left at least below the rectangular upper electrodes 7, and the lower electrode 5 is then patterned by the photolithography method such that a part of the lower electrode 5 is exposed from the oxide dielectric film 6. Since the oxide dielectric film 6 is damaged by the photolithography method, the oxygen-annealing is then performed at the substrate temperature of 550° C. for 60 minute in order to restore the film quality of the oxide dielectric film 6.

After above patterning has been finished, the upper electrodes 7, the oxide dielectric film 6, and the lower electrode 5 have their sectional shapes, as shown in FIG.1C, respectively.

Then, as shown in FIG.1D, a second interlayer insulating film 8 made of silicon dioxide is formed on the capacitors Q and the first interlayer insulating film 4 to have a thickness of 200 nm. The second interlayer insulating film 8 is grown at the substrate temperature of 390° C. by vaporizing TEOS (tetra ethoxy silane), which is organic silicon compound having low reduction property, and then introducing it into the reaction atmosphere together with the carrier gas.

The first interlayer insulating film 4 and the second interlayer insulating film 8 are then patterned by the photolithography method. Thus, as shown in FIG.1E, first openings 8a for exposing the first impurity diffusion layers 3d of the MOS transistors 3 respectively, a second opening 8b for exposing a part of the lower electrode 5, and third openings 8c for exposing a part of the upper electrodes 7 respectively are formed. With the use of resist, patterning of the first interlayer insulating film 4 and the second interlayer insulating film 8, both being formed of SiO₂, are executed by the plasma etching using a gas containing fluorine (F).

Since the oxide dielectric film 6 is damaged via the third openings 8c and the upper electrodes 7 in forming and patterning the second interlayer insulating film 8, the oxide dielectric film 6 is annealed in the oxygen atmosphere at the substrate temperature of 550° C. in order to recover a normal state of the damaged oxide dielectric film 6.

Then, as shown in FIG.1F, a titanium nitride (TiN) film 9 of 100 nm thickness is formed on the second interlayer insulating film 8 and in the first to third openings 8a to 8c by the reactive sputter method. By patterning the TiN film 9 by virtue of the photolithography method, local interconnections 9a which connect the upper electrodes 7 and the impurity diffusion layers 3d via the first openings 8a and the third openings 8c respectively are formed and simultaneously a lower electrode leading wiring 9b which extends the lower electrode 5 to the external device is formed.

The local interconnections 9a are patterned to cover the rectangular upper electrodes 7 respectively, as shown in FIG.2B. In this case, since it is possible to miniaturize the TiN film 9 serving as the local interconnections 9a by the photolithography, the local interconnections 9a can be patterned such that a distance between a plurality of local interconnections 9a which cover a plurality of upper electrodes 7 separately is set to 1 μm to 0.4 μm.

Then, as shown in FIG.1G, a third interlayer insulating film 10 is formed under the same conditions as those in growing the second interlayer insulating film 8 using TEOS. Thus, the local interconnections 9a and the lower electrode leading wiring 9b are covered with the third interlayer insulating film 10. In addition, an SOG film 11 is formed by coating a solution, in which silicon compound is solved into an organic solvent, on the third interlayer insulating film 10 and then firing the solution.

Hydrogen is contained in the material which is employed in growing the third interlayer insulating film 10 and the SOG film 11. However, since the oxide dielectric film 6 formed below the upper electrodes 7 is covered with the local interconnections 9a formed of TiN which does not transmit the hydrogen, the damage of the oxide dielectric film 6 due to the reduction action is hardly caused. Accordingly, no oxygen-annealing of the oxide dielectric film 6 is needed after the third interlayer insulating film 10 and the SOG film 11 have been formed. As a result, there is no possibility that the local interconnections 9a and the lower electrode leading wiring 9b are oxidized.

Then, by patterning the third interlayer insulating film 10 and the SOG film 11 by virtue of the photolithography method, a fourth opening 11a is formed on the lower electrode leading wiring 9b and simultaneously fifth openings 11b are formed on the second impurity diffusion layers 3s of the MOS transistors 3. A first wiring 12 which is connected to the lower electrode leading wiring 9b via the fourth opening 11a is then formed on the SOG film 11. Second wirings 13 which are connected to the second impurity diffusion layers 3s via the fifth openings 11b are then formed on the SOG film 11. The first wiring 12 and the second wirings 13 are composed of a quadruple-layered film which consists of titanium, titanium nitride, aluminum, and titanium nitride, respectively.

Electric characteristics of the capacitors Q in the semiconductor device formed according to the above-mentioned steps will be evaluated in the following.

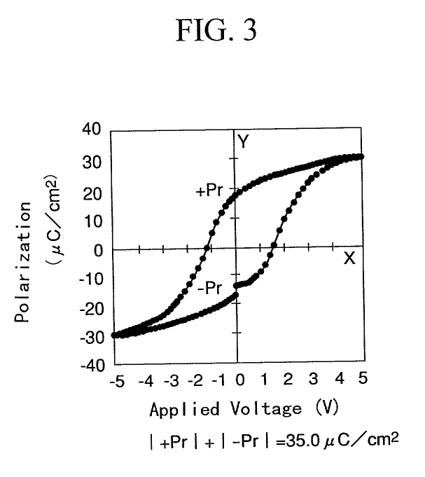

When a hysteresis curve of polarization of the capacitor Q and an applied voltage is checked, a result shown in FIG.3 has been derived. In FIG.3, two intercepts of the hysteresis curve on the y-axis are called spontaneous polarization (Pr) which acts as an index for indicating ferroelectricity. A value of |+ Pr |+|−Pr |has become 35.0 μC/cm² by calculation.

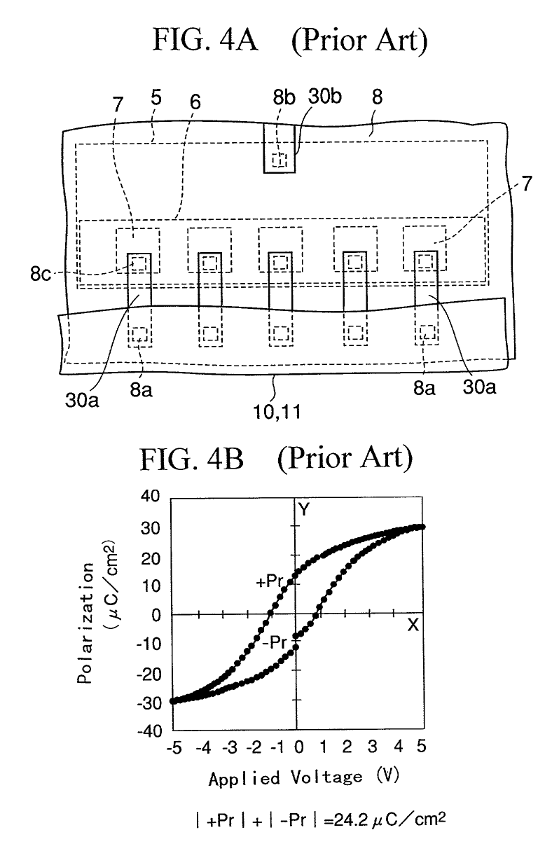

On the contrary, as shown in FIG.4A, in the semiconductor device in which local interconnections 30a each having a width narrower than that of the upper electrode 7 of the capacitor Q are formed, a hysteresis curve of the capacitor Q can be given as shown in FIG.4B. A value of |+ Pr |+|− Pr |has become 24.2 μ C/cm² by calculation. The cause of reduction in the spontaneous polarization like the above may be supposed as that the oxide dielectric film 6 made of ferroelectric material lacks the oxygen due to the reduction action of the hydrogen, which is generated in forming the third interlayer insulating film 10 and the SOG film 11 on the local interconnections 30a, to thus cause reduction in a dielectric constant.

Therefore, it has been found that, as shown in FIG.2B, formation of the local interconnections 9a made of metal nitride in the range overlapping on the rectangular upper electrodes 7 is effective at preventing the damage of the oxide dielectric film 6 due to the reduction gas being generated in forming the insulating film on the local interconnections 9a.

In the above examples, the local interconnections 9a are formed by the titanium nitride. However, the local interconnections 9a may be formed by a metal like nitride alloy such as tungsten nitride, titanium-tungsten nitride, etc., which does not have hydrogen permeability and whose fine patterning can be easily made.

In the above examples, the PLZT and the PZT are employed as the oxide dielectric film 6 made of ferroelectric material. However, ferroelectrics such as (Ba,Sr)TiO₃, Pb(Zr,Ti)O₃, (Pb,La)(Zr,Ti)O₃, SrBi₂Ta₂O₉, Ta₂O₃, etc. may be employed. In this case, it is possible to fabricate the capacitors having good characteristics by adopting the above local interconnections 9a.

Further, iridium (Ir), ruthenium (Ru), or conductive ceramics may be selected in addition to platinum (Pt) as constituent material of the upper electrodes 7.

A reference 30b in FIG.4A denotes a lower electrode leading wiring.

Second Embodiment

In the first embodiment, since the substantial size of the capacitor Q is defined according to sizes of the rectangular upper electrodes 7 as described above, miniaturization of the capacitor Q is restricted by a working precision of the upper electrode 7.

Therefore, in the second embodiment, formation of the capacitor which is not restricted by the pattern precision of the upper electrodes 7 will be explained hereunder.

At first, like the first embodiment, the lower electrode 5 and the oxide ferroelectric film 6 are formed on the first interlayer insulating film 4 in the state shown in FIG.1A.

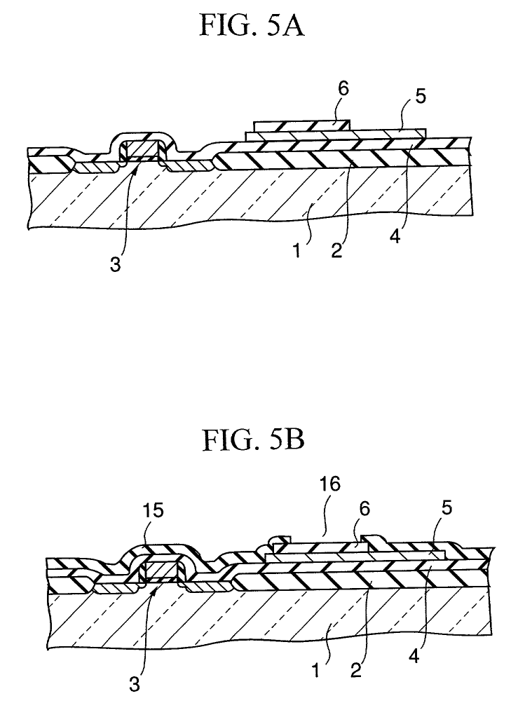

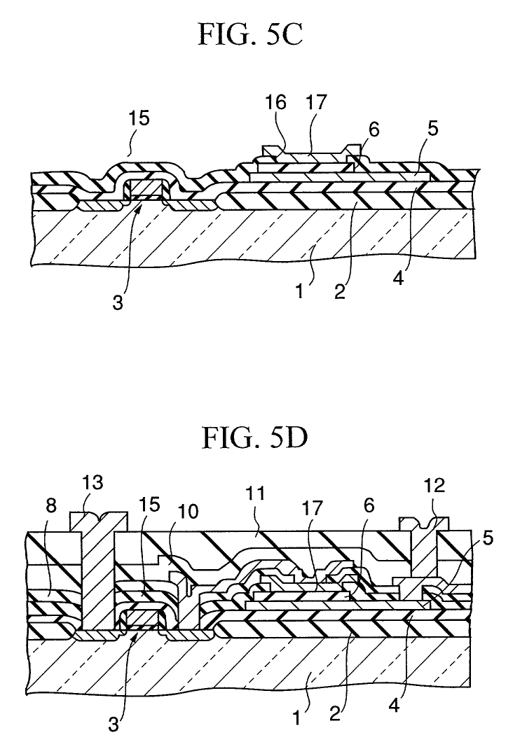

The lower electrode 5 and the oxide ferroelectric film 6 are then patterned into the same shapes as those in the first embodiment by the photolithography method. Their sectional shapes are given as shown in FIG.5A.

An intermediate insulating film 15 for covering the first interlayer insulating film 4 is formed under the same conditions as those of the second interlayer insulating film 8 using the above TEOS. Then, as shown in FIG.5B, windows 16 for defining the areas of the capacitor Q respectively are formed by patterning the intermediate insulating film 15, so that a part of the oxide ferroelectric film 6 is exposed from the windows 16. Planar shapes and positions and largeness of the windows 16 become identical to those of the upper electrodes 7 shown in FIG.2A.

A 175 nm thick platinum film is then formed on the intermediate insulating film 15 and in the windows 16. Then, as shown in FIG.5C, the platinum film is patterned to be left in the windows 16 and their peripheral regions, so that the left platinum films are employed as upper electrodes 17.

After this, in order to eliminate the damage of the oxide ferroelectric film 6 caused at the time of formation of the upper electrodes 17 and formation of the intermediate insulating film 15, the oxygen-annealing is applied.

Like the first embodiment, the second interlayer insulating film 8 is then formed, then the first openings 8a to the third openings 8c are formed in the second interlayer insulating film 8, and then the local interconnections 9a for covering the windows 16 are formed to define at least the positions of the capacitors Q.

The steps carried out after the local interconnections 9a have been formed are similar to those in the first embodiment. In the end, as shown in FIG.5D, a sectional shape of the semiconductor device according to a second embodiment is formed.

As discussed above, since it is designed that the positions and the size of the capacitors Q would be defined by the windows 16, the positions and the size of the capacitors Q are restricted according to the pattern precision of the intermediate insulating film 15. Thus, the pattern precision of the intermediate insulating film 15, i.e., the silicon dioxide film becomes higher than that of the metal film such as titanium nitride, etc. As a result, finer capacitor shapes can be achieved with good reproducibility.

Even if the structure of the second embodiment is employed, degradation of the capacitors Q due to the reduction gas (hydrogen) can be suppressed since the local interconnections 9a connected to upper electrodes 14 are arranged to cover the capacitors Q like the first embodiment.

In case the structure of the second embodiment is adopted, the silane gas may be employed to form the intermediate insulating film 15 prior to formation of the upper electrodes 17. This is because the upper electrodes have not been formed on the oxide ferroelectric film 6 yet and thus there is no necessity that film peeling of the upper electrodes due to degradation in film quality of the oxide ferroelectric film 6 should be taken account at this stage. A large quantity of hydrogen is generated when the silane gas is employed, so that the film quality of the oxide dielectric film is deteriorated. However, the film quality of the oxide dielectric film can be restored by performing the oxygen-annealing succeedingly. Since the silicon oxide film which employs the silane as material has fine film quality and is hard to absorb moisture rather than the silicon oxide film which employs organic silicon as material, the ferroelectric memory device which has excellent moisture resistance can be implemented if the silane gas is employed as the material gas.

Third Embodiment

In the first and second embodiments of the present invention, as shown in FIG.1F and FIG.5D, the local interconnections 9a are connected directly to the impurity diffusion layers 3d. In this event, plugs may be filled in the first openings 8a which are formed on the impurity diffusion layers respectively and then the local interconnections 9a may be connected to the impurity diffusion layers 3d via the plugs.

Therefore, the step of forming the plugs and the step of connecting the plugs and the local interconnections 9a will be explained hereunder. The structure in the first embodiment will be employed as the capacitor structure to be described in the following, but the structure in the second embodiment may also be employed.

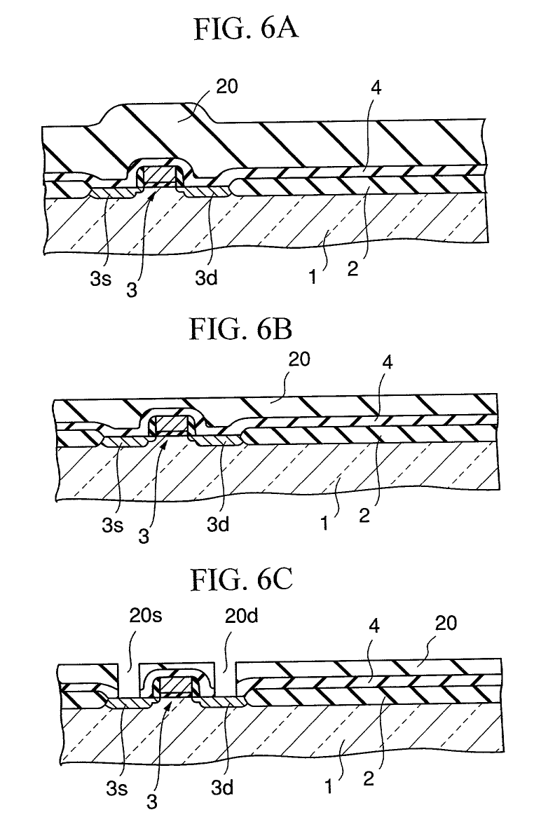

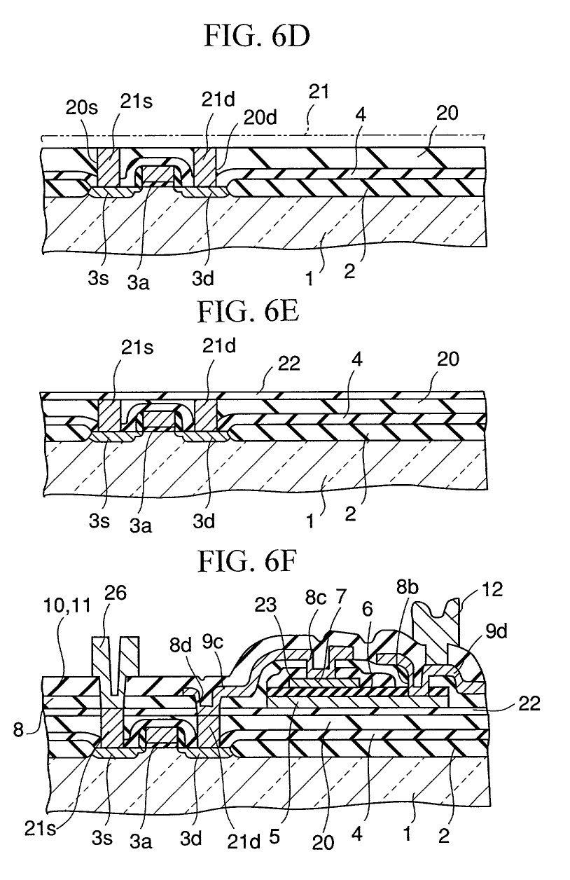

At first, as shown in FIG.6A, the first interlayer insulating film 4 is formed to have a thickness of 200 nm, and then a fourth interlayer insulating film 20 is formed on the first interlayer insulating film 4 to have a thickness of 1000 nm. In this case, silicon nitride oxide is employed as material constituting the first interlayer insulating film 4, and silicon oxide is employed as material constituting the fourth interlayer insulating film 20.

Then, as shown in FIG.6B, the fourth interlayer insulating film 20 is planarized by the CMP (Chemical Mechanical Polishing) method. This polishing is stopped at the location where the first interlayer insulating film 4 covering the gate electrode 3g which extends as the word line on the field oxide film 2 is exposed.

Then, as shown in FIG.6C, first openings 20d and fourth openings 20s are formed on the first impurity diffusion layers 3d and the second impurity diffusion layers 3s respectively by patterning the first interlayer insulating film 4 and the fourth interlayer insulating film 20 by virtue of the photolithography method.

Then, as shown in FIG.6D, a tungsten film 21 is formed on the fourth interlayer insulating film 20 and in the first openings 20d and the fourth openings 20s. The tungsten film 21 is polished by the CMP method to be left only in the first openings 20d and the fourth openings 20s. The tungsten film 21 left in the first openings 20d is used as first plugs 21d, while the tungsten film 21 left in the fourth openings 20s is used as second plugs 21s.

Then, as shown in FIG.6E, in order to prevent oxidation of surfaces of the first plugs 21d and the second plugs 21s filled in the first openings 20d and the fourth openings 20s respectively, an oxidation preventing film 22 is formed on the fourth interlayer insulating film 20, the first plugs 21d, and the second plugs 21s. It is preferable to employ the silicon nitride or the silicon nitride oxide as constituent material of the oxidation preventing film 22.

Then, as shown in FIG.6F, the capacitors consisting of the lower electrode 5, the dielectric film 6, and the upper electrodes 7 are formed via the steps explained in the first embodiment. In this case, the dielectric film 6 has the same planar shape as the lower electrode 5.

After this, a fifth interlayer insulating film 23 covering the lower electrode 5 is formed and then the second interlayer insulating film 8 is formed in the same way as the first embodiment. Then, the second opening 8b for exposing the lower electrode 5, the third openings 8c for exposing a part of the upper electrodes 7, and fifth openings 8d for exposing the first plugs 21d are formed by patterning the second interlayer insulating film 8, the fifth interlayer insulating film 23, and the dielectric film 6.

As in the first embodiment, the local interconnections 9c which have their size to overlap with the upper electrodes 7 and which extend from the third openings 8c to the fifth openings 8d respectively are formed on the second interlayer insulating film 8. At the same time, the lower electrode leading wiring 9b is formed to extend from the second opening 8b over the second interlayer insulating film 8.

Then, the third interlayer insulating film 10 and the SOG film 11 are formed via the same steps as those in the first embodiment, and the first wiring 12 and the second wirings 13 are then formed.

As described above, according to the present invention, the capacitors are covered with the local interconnections whose fine patterning can be achieved and also the upper electrodes of the capacitors and the impurity diffusion layers are connected by the local interconnections respectively. Therefore, individual capacitors can be covered with the local interconnections without fail if the capacitors employing the oxide dielectric film are fabricated with a high integration density. As a result, hydrogen diffusion into the capacitors can be prevented by the local interconnections even when the hydrogen is generated in forming the insulating film on the local interconnections, and thus the succeeding oxygen-annealing of the oxide dielectric film can be omitted and also the oxidation of the local interconnections can be prevented.

In addition, the windows are opened in the insulating film which is formed on the oxide dielectric film, and then the oxide dielectric film and the upper electrodes are connected via the windows. Therefore, a higher integration density of the capacitors can be achieved according to the size of the windows which are formed in the insulating film and which enable higher precision of the patterning.

What is claimed is:

1. A method of manufacturing a semiconductor device comprising the steps of:
forming an impurity diffusion layer in a semiconductor substrate;
forming a first insulating film covering the semiconductor substrate;
forming a lower electrode of a capacitor on the first insulating film;
forming an oxide dielectric film of the capacitor on the lower electrode;
forming an upper electrode of the capacitor on the oxide dielectric film;
forming a second insulating film for covering the capacitor;
forming a first opening on or above the impurity diffusion layer and a second opening on the upper electrode in the first and second insulating films, by etching a part of the second insulating film and a part of the first insulating film;
forming an oxidation-preventing metal film on the second insulating film for connecting electrically the diffusion layer via the first opening and the upper electrode via the second opening;
forming a local interconnection in a range which pass through the first opening and the second opening and contains at least a region where the upper electrode contacts the oxide dielectric film, by patterning the oxidation-preventing metal film; and
forming a third insulating film for covering the local interconnection.

2. A method of manufacturing a semiconductor device according to claim 1, wherein the oxidation-preventing metal film constituting the local interconnection is formed of metal nitride.

3. A method of manufacturing a semiconductor device according to claim 2, wherein the metal nitride is one of titanium nitride, tungsten nitride or titanium-tungsten nitride.

4. A method of manufacturing a semiconductor device according to claim 1, wherein the step of forming the capacitor comprises the steps of,
setting the upper electrode into a size which defines a capacitor region by patterning the upper electrode,
leaving the oxide dielectric film at least below the upper electrode by patterning the oxide dielectric film, and
setting the lower electrode into a size which is wider than the oxide dielectric film by patterning the lower electrode.

5. A method of manufacturing a semiconductor device according to claim 1, wherein the step of forming the capacitor comprises the steps of,
patterning the oxide dielectric film and the lower electrode,
forming an intermediate insulating film for covering the oxide dielectric film and the lower electrode,
forming a window, which is employed to define the capacitor region, in the intermediate insulating film by patterning the intermediate insulating film, and
forming the upper electrode at least in the window.

6. A method of manufacturing a semiconductor device according to claim 1, wherein the second insulating film for covering the capacitor or the third insulating film is a silicon oxide film which is formed by using silane.

7. A method of manufacturing a semiconductor device according to claim 1, wherein the second insulating film is a silicon oxide film which is formed by using organic silicon compound source.

8. A method of manufacturing a semiconductor device according to claim 7, wherein the organic silicon compound source is tetra ethoxy silane.

9. A method of manufacturing a semiconductor device according to claim 1, wherein the oxide dielectric film is oxygen-annealed before and/or after the upper electrode of the capacitor is formed.

10. A method of manufacturing a semiconductor device according to claim 1, further comprising the step of oxygen-annealing the oxide dielectric film via the second opening and the upper electrode after forming the second opening.

11. A method of manufacturing a semiconductor device according to claim 1, wherein the upper electrode is formed of a noble metal or a conductive ceramic which is not oxidized by the oxygen-annealing.

12. A method of manufacturing a semiconductor device according to claim 11, the noble metal is one of platinum, iridium or ruthenium.

13. A method of manufacturing a semiconductor device according to claim 1, wherein the oxide dielectric film is formed of PLZT, PZT, (Ba,Sr)TiO₃, Pb(Zr,Ti)O₃, (Pb,La)(Zr,Ti)O₃, SrBi₂Ta₂O₉ or Ta₂O₃.

14. A method of manufacturing a semiconductor device according to claim 1 further comprising the step of:
forming a conductive plug between the oxidation-preventing metal film and the diffusion layer in the first opening.

15. A method of manufacturing a semiconductor device according to claim 14, wherein the conductive plug is formed of tungsten.

16. A method of manufacturing a semiconductor device according to claim 1, wherein the impurity diffusion layer is a component part of an MOS transistor.

17. A semiconductor device comprising:
an impurity diffusion layer formed on a semiconductor substrate;
a first insulating film for covering the impurity diffusion layer and a semiconductor substrate;
a capacitor formed on the first insulating film and consisting of a lower electrode, an oxide dielectric film, and an upper electrode;
a second insulating film for covering the capacitor;
first and second openings formed in the second insulating film to on or above the impurity diffusion layer and the upper electrode;
a local interconnection connected electrically with the impurity diffusion layer and the upper electrode respectively through the first and second openings and formed on the second insulating film in a range containing at least a region where the upper electrode contacts the oxide dielectric film; and
a third insulating film for covering the local interconnection.

18. A semiconductor device according to claim 17 further comprising,
a conducting plug formed between the impurity diffusion layer and the upper electrode in the first opening.

19. A semiconductor device according to claim 17, wherein the local interconnection is composed of metal nitride.

20. A semiconductor device according to claim 19, wherein the metal nitride is one of titanium nitride, tungsten nitride or titanium-tungsten nitride.
